(19) United States
(12) Patent Application Publication
(10) Pub. No.: US 2014/0104787 A1
(43) Pub. Date: Apr. 17, 2014

(54) INTERCHANGEABLE COOLING SYSTEM FOR INTEGRATED CIRCUIT AND CIRCUIT BOARD

(71) Applicant: International Business Machines Corporation, Armonk, NY (US)

(72) Inventors: Timothy J. Chainer, Putnam Valley, NY (US); David P. Graybill, Staatsburg, NY (US); Madhusudan K. Iyengar, Woodstock, NY (US); Vinod Kamath, Raleigh, NC (US); Bejoy J. Kochuparambil, Apex, NC (US); Roger R. Schmidt, Poughkeepsie, NY (US); Mark E. Steinke, Durham, NC (US)

(73) Assignee: International Business Machines Corporation, Armonk, NY (US)

(21) Appl. No.: 14/106,840

(22) Filed: Dec. 15, 2013

Related U.S. Application Data
(62) Division of application No. 13/361,929, filed on Jan. 30, 2012.

(51) Int. Cl. H05K 7/20

(52) U.S. Cl. CPC H05K 7/20009; H05K 7/20254
USPC 361/690

(57) ABSTRACT

Several apparatuses and methods for providing cooling system interchangeability. One apparatus includes a thermally conductive plate thermally coupled to an integrated circuit. The thermally conductive plate is configured to couple interchangeably to a liquid cooling assembly or an air cooling assembly, and the liquid cooling assembly and the air cooling assembly are separate devices.

### CROSS-REFERENCE TO RELATED APPLICATIONS

This application is a divisional application of and claims priority under 35 U.S.C. §121 to U.S. patent application Ser. No. 13/361,929 (“INTERCHANGEABLE COOLING SYSTEM FOR INTEGRATED CIRCUIT AND CIRCUIT BOARD”) filed Jan. 30, 2012, the entire text of which is specifically incorporated by reference herein.

### GOVERNMENT LICENSE RIGHTS

This invention was made with the United States Government support under Agreement No. DE-EE0002894 awarded by the Department of Energy. The Government has certain rights in the invention.

### BACKGROUND

The present invention is directed towards computer cooling devices and, more particularly, to devices for facilitating cooling of integrated circuits on a circuit board.

Some manufacturers allow consumers to purchase a common product with a variety of cooling mechanisms. Each cooling mechanism may require a different top level assembly because the cooling structures are different. Thus, a manufacturer may have to build different top level assemblies on the common product. Additionally, a manufacturer may produce a certain number of products with one type of top level assembly in anticipation of consumer demand, but consumer demand may change, causing the manufacturer to store the unused product.

### BRIEF SUMMARY

An example embodiment of the present invention is an apparatus for providing cooling system interchangeability. The apparatus includes a thermally conductive plate thermally coupled to an integrated circuit. The thermally conductive plate is configured to couple interchangeably to a liquid cooling assembly or an air cooling assembly, and the liquid cooling assembly and the air cooling assembly are separate devices.

Another example embodiment of the present invention is a method for providing cooling system interchangeability. The method includes thermally coupling a thermally conductive plate to an integrated circuit. The thermally conductive plate is configured to couple interchangeably to a liquid cooling assembly or an air cooling assembly, and the liquid cooling assembly and the air cooling assembly are separate devices.

A further example embodiment of the invention is another apparatus for providing cooling system interchangeability. The apparatus includes a thermally conductive encasement configured to enclose an integrated circuit and to couple interchangeably to a liquid cooling assembly or an air cooling assembly. The encasement is at least partially filled with a dielectric fluid thermally coupling the integrated circuit to the encasement. The dielectric fluid is not circulated out of the encasement, and the liquid cooling assembly and the air cooling assembly are separate devices.

Yet a further example embodiment of the invention is another method for providing cooling system interchangeability. The method includes enclosing an integrated circuit by a thermally conductive encasement configured to couple interchangeably to a liquid cooling assembly or an air cooling assembly. The encasement is at least partially filled with a dielectric fluid thermally coupling the integrated circuit to the encasement. The dielectric fluid is not circulated out of the encasement, and the liquid cooling assembly and the air cooling assembly are separate devices.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 shows an example embodiment of an apparatus for providing cooling system interchangeability.

FIG. 2 shows an example embodiment of the apparatus of FIG. 1 coupled to an example air cooling assembly.

FIG. 3 shows an example embodiment of the apparatus of FIG. 1 coupled to an example liquid cooling assembly.

FIG. 4 shows an example embodiment of another apparatus for providing cooling system interchangeability.

FIG. 5 shows an example embodiment of an apparatus that does not include a spring wire mechanism.

FIG. 6 shows a top-down view of another example embodiment of an apparatus.

FIG. 7 shows an embodiment of the apparatus of FIG. 4 coupled to an example air cooling assembly.

FIG. 8 shows an embodiment of the apparatus of FIG. 4 coupled to an example liquid cooling assembly.

FIG. 9 shows a top-down view of the example embodiment shown in FIG. 8.

FIG. 10 shows an example embodiment of a method for providing cooling system interchangeability.

FIG. 11 shows an example embodiment of another method for providing cooling system interchangeability.

### DETAILED DESCRIPTION

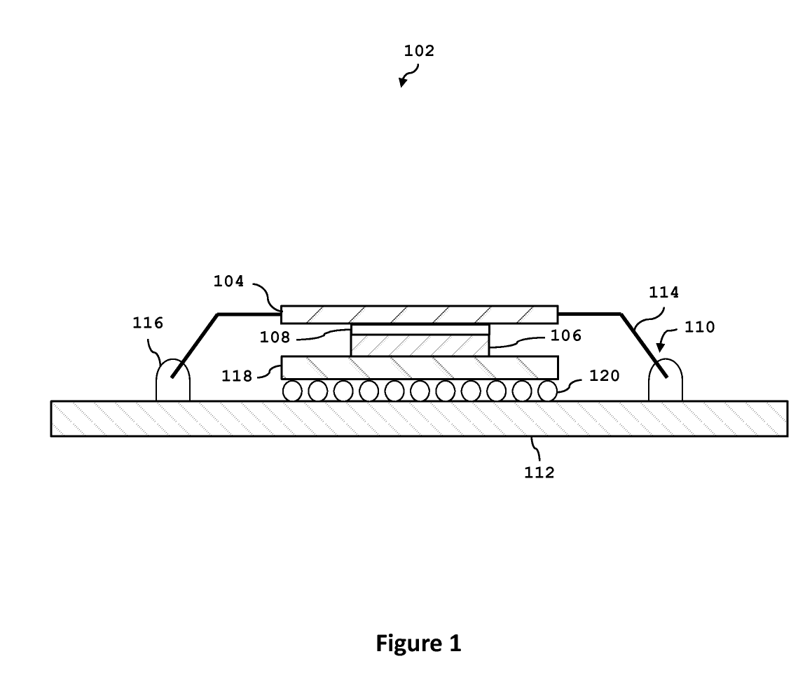

The present invention is described with reference to embodiments of the invention. Throughout the description of the invention reference is made to FIGS. 1-11. As discussed in detail below, embodiments of the present invention include apparatuses and methods for providing cooling system interchangeability.

FIG. 1 shows an example embodiment of an apparatus 102 for providing cooling system interchangeability. The apparatus 102 may include a thermally conductive plate 104. For example, the thermally conductive plate 104 may be aluminum, copper, or other suitable material to meet design requirements. The thermally conductive plate 104 may be thermally coupled to an integrated circuit 106.

In one embodiment, the apparatus 102 includes an inner thermal interface material 108 disposed between the thermally conductive plate 104 and the integrated circuit 106. Example embodiments of the inner thermal interface material 108 include thermal epoxy, thermal grease, phase change material, a thermal gap pad, or other suitable heat transferring material. The apparatus 102 may further include a spring wire mechanism 110 configured to fasten the thermally conductive plate 104 to a printed circuit board 112. In one embodiment, the spring wire mechanism 110 has two or more wire springs 114, and each wire spring 114 is connected to a corresponding wire bail 116. The wire bail 116 may be configured to attach to the printed circuit board 112. For example, the wire bail 116 may be a wire loop connected to the printed circuit board 112 and capable of being connected to the wire springs 114. In another embodiment, the wire springs 114 may be attached to the printed circuit board 112 with push pins. Alternatively, one end of each of the wire springs 114 may be permanently fixed to the printed circuit board 112.

In one embodiment, the integrated circuit 106 is above a ceramic base 118. The ceramic base 118 may be electrically connected to the printed circuit board 112 through a ball grid array including solder balls 120 between the printed circuit board 112 and ceramic base 118. In some embodiments, other packaging techniques known in the art may be appropriate to meet the design needs of the apparatus 102.

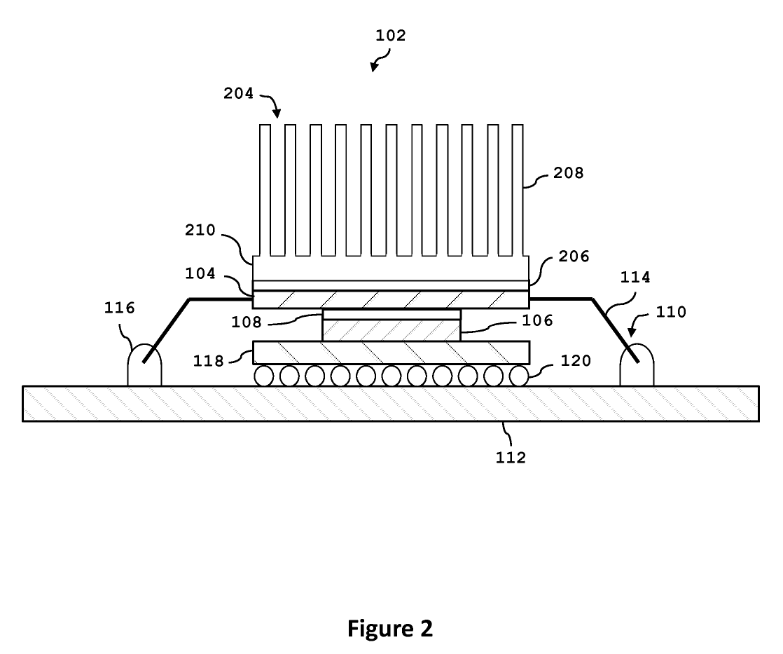

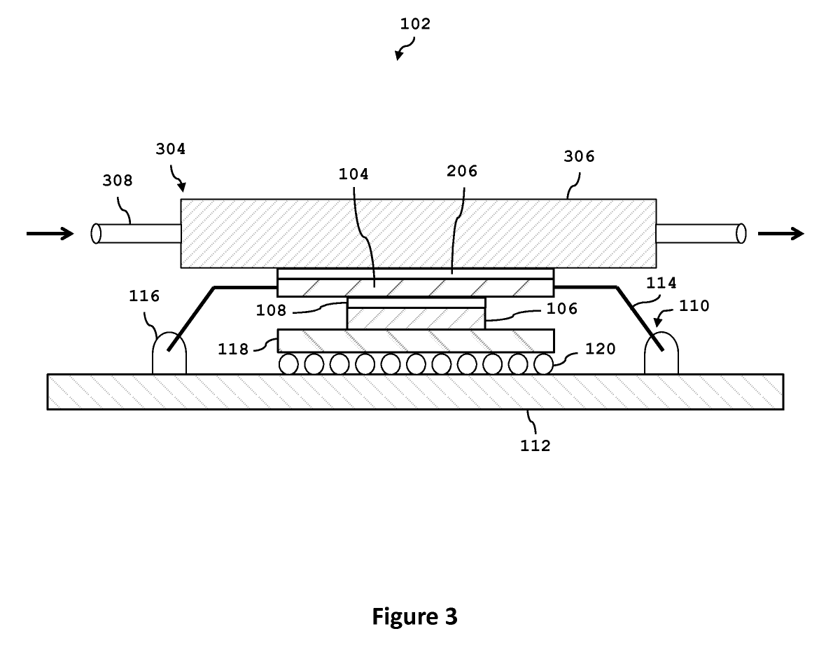

FIGS. 2 and 3 show example embodiments of the apparatus 102 coupled to various cooling assemblies. In one embodiment, the thermally conductive plate 104 is configured to couple interchangeably to an air cooling assembly 204 (see FIG. 2) and a liquid cooling assembly 304 (see FIG. 3). It is noted that the liquid cooling assembly 304 and the air cooling assembly 204 may be separate devices. As shown in FIGS. 2 and 3, the apparatus 102 may include an outer thermal interface material 206 disposed between the thermally conductive plate 104 and one of the air cooling assembly 204 and liquid cooling assembly 304. The outer thermal interface material 206 may thermally couple the thermally conductive plate 104 and the air cooling assembly 204 or liquid cooling assembly 304. Example embodiments of the outer thermal interface material 206 include thermal epoxy, thermal grease, phase change material, a thermal gap pad, or other suitable heat transferring material.

FIG. 2 shows an example embodiment of the apparatus 102 coupled to an example air cooling assembly 204. The outer thermal interface material 206 may be disposed between the thermally conductive plate 104 and the air cooling assembly 204. In one embodiment, the air cooling assembly 204 includes a heat sink configured to dissipate heat into air. The heat sink may include heat radiating fins 208 on a fin base 210.

FIG. 3 shows an example embodiment of the apparatus 102 coupled to an example liquid cooling assembly 304. The outer thermal interface material 206 may be disposed between the thermally conductive plate 104 and the liquid cooling assembly 304. In one embodiment, the liquid cooling assembly includes a cold plate 306 configured to receive liquid from piping 308. The piping 308 may be configured to carry liquid to and from the cold plate 306. An example cold plate 306 may include a plate of aluminum or other suitable metal with liquid passages inside the plate.

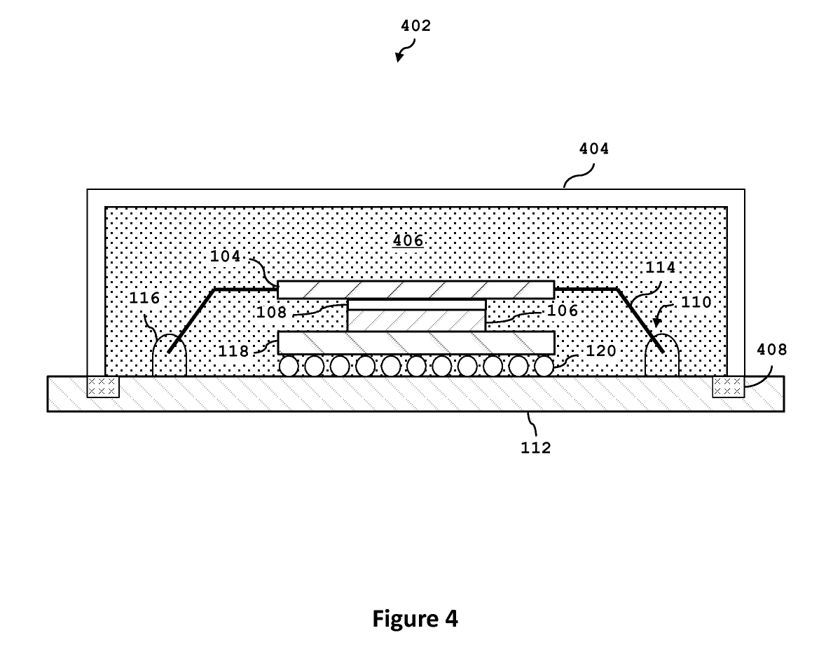

FIG. 4 shows an example embodiment of another apparatus 402 for providing cooling system interchangeability. The apparatus 402 may include a thermally conductive encasement 404 configured to enclose an integrated circuit and to couple interchangeably to a liquid cooling assembly 304 and an air cooling assembly 204. The encasement 404, for example, may be copper, aluminum, or other suitable material. In some applications, the encasement 404 may be a thermally conductive plastic.

In one embodiment, the encasement 404 is at least partially filled with a dielectric fluid 406 thermally coupling the integrated circuit 106 to the encasement 404. Example dielectric fluids include dielectric refrigerants such as FC-72, FC-77, FC-87, HFE7000, HFE7100, HFE7200 or other dielectric fluids suitable to match the device fabrication requirements. The dielectric fluid 406 may not be circulated out of the encasement 404. In one embodiment, the dielectric fluid 406 is deposited in the encasement 404 by a fill tube in a wall of the encasement 404. After the dielectric fluid 406 is deposited in the encasement 404, the fill tube may be filled in or crimped closed to prevent the dielectric fluid 406 from circulating outside of the encasement 404. Additionally, the liquid cooling assembly 304 and the air cooling assembly 302 may be separate devices.

In one embodiment, the apparatus 402 includes a printed circuit board 112 carrying the integrated circuit 106. The encasement 404 may also be attached to the printed circuit board 112. For example, the printed circuit board 112 may include metallic traces 408 configured to attach the encasement 404 to the printed circuit board 112. In one embodiment, the metallic traces 408 include copper. The encasement 404 may be soldered to the metallic traces 408 in such a manner as to prevent the dielectric fluid 406 from leaking out of the encasement 404.

In one embodiment, the apparatus 402 includes a thermally conductive plate 104 thermally coupled to the integrated circuit 106 and enclosed by the encasement 404. The thermally conductive plate 104 may be configured to couple interchangeably to the liquid cooling assembly 304 and the air cooling assembly 204 in the absence of the encasement.

The apparatus 404 may include a spring wire mechanism 110 configured to fasten the thermally conductive plate 104 to a printed circuit board 112. In one embodiment, the spring wire mechanism 110 has two or more wire springs 114, and each wire spring 114 may be connected to a corresponding wire bail 116. The wire bail 116 may be configured to attach to the printed circuit board 112.

In one embodiment, the integrated circuit 106 is above a ceramic base 118. The ceramic base 118 may be electrically connected to the printed circuit board 112 through a ball grid array including solder balls 120 between the printed circuit board 112 and ceramic base 118. In some embodiments, other packaging techniques known in the art may be appropriate to meet the design needs of the apparatus 402.

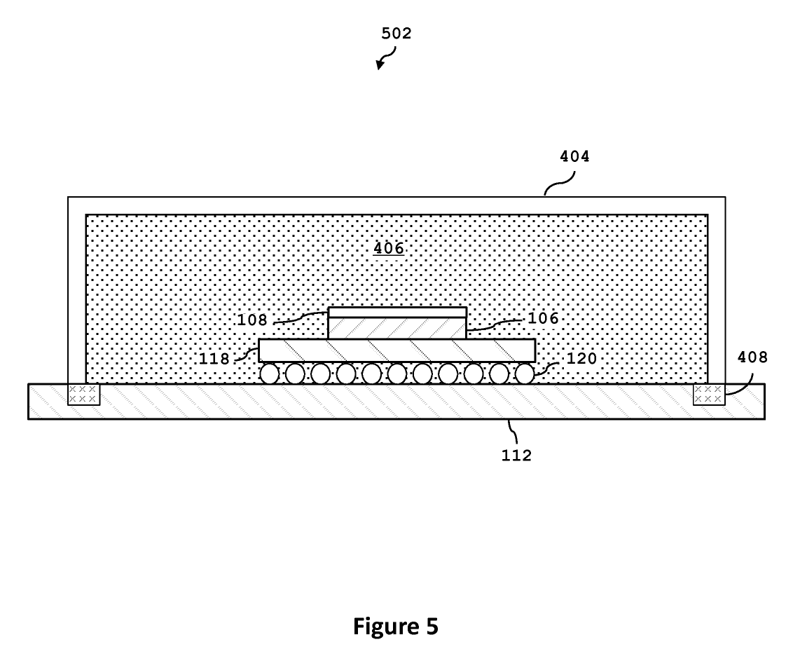

FIG. 5 shows an example embodiment of an apparatus 502 that does not include a spring wire mechanism. The apparatus 502 may include many of the features of the apparatus 402 described above. In one embodiment, the apparatus 502 includes a printed circuit board 112 carrying the integrated circuit 106. The apparatus 502 may also include an inner thermal interface material 108 above the integrated circuit 106. Example embodiments of the inner thermal interface material 108 include thermal epoxy, thermal grease, phase change material, a thermal gap pad, or other suitable heat transferring material.

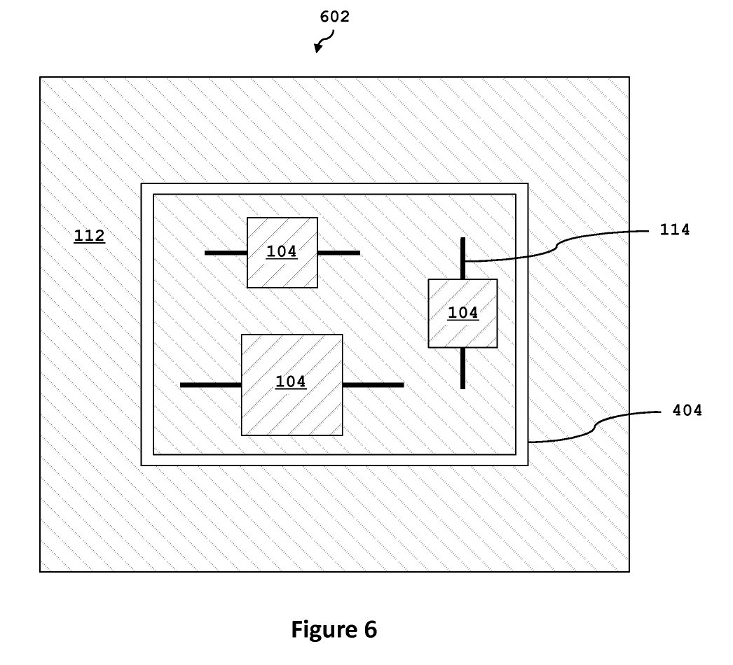

FIG. 6 shows a top-down view of another example embodiment of an apparatus 602. The apparatus 602 may include many of the features of the apparatus 402 described above. In this embodiment, however, the encasement 404 (shown as a cross-section from this perspective) encloses more than one integrated circuit 106 on the printed circuit board 112 and less than the entire printed circuit board 112. In the example embodiment shown in FIG. 6, the encasement 404 encloses three integrated circuits 106, but it is contemplated that a different number of integrated circuits may be enclosed according to the design and requirements of the particular embodiment.

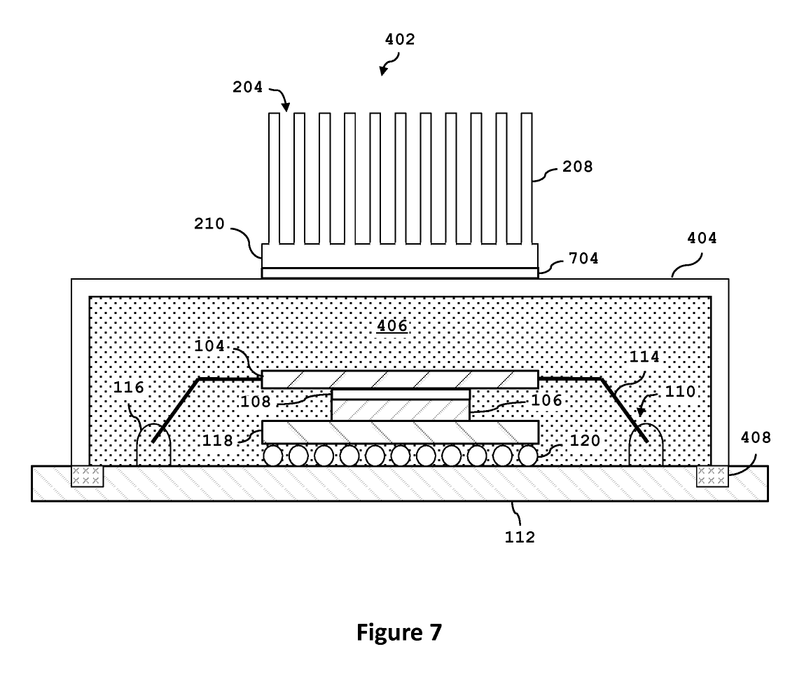

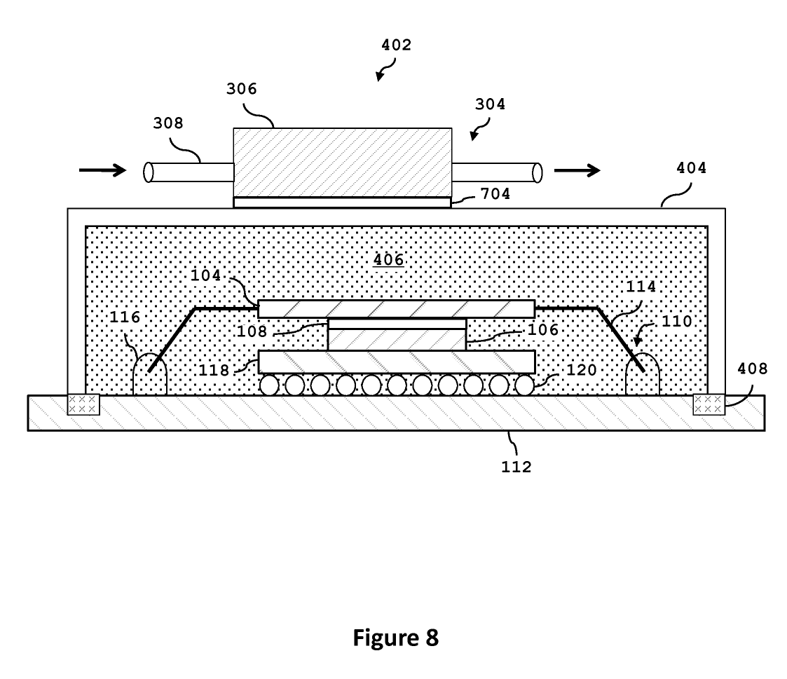

FIGS. 7 and 8 show the encasement 404 of the apparatus 402 coupled to either the air cooling assembly 204 or liquid cooling assembly 304. As shown in FIGS. 7 and 8, the apparatus 402 may include an outer thermal interface material 704 configured to thermally couple the encasement 404 and the air cooling assembly 204 or the liquid cooling assembly 304. Example embodiments of the outer thermal interface material 704 include thermal epoxy, thermal grease, phase change material, a thermal gap pad, or other suitable heat transferring material.

FIG. 7 shows an embodiment of the apparatus 402 coupled to an example air cooling assembly. FIG. 7 also shows the outer thermal interface material 704 between the encasement and an example air cooling assembly 204. In one embodiment, the air cooling assembly 204 includes a heat sink configured to dissipate heat into air. The heat sink may include heat radiating fins 208 on a fin base 210.

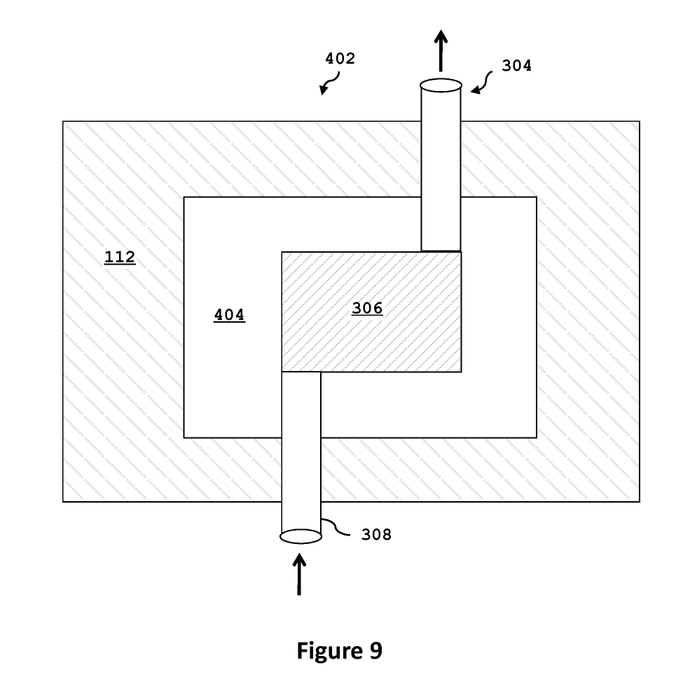

FIG. 8 shows an embodiment of the apparatus 402 coupled to an example liquid cooling assembly 304. FIG. 8 also shows the outer thermal interface material 704 between the encasement 404 and an example liquid cooling assembly 304. In one embodiment, the liquid cooling assembly 304 includes a cold plate 306 configured to receive liquid from piping 308. The piping 308 may be configured to carry the liquid to and from the cold plate 306. An example cold plate 306 may include a plate of aluminum or other suitable metal with liquid passages inside the plate. FIG. 9 shows a top-down view of the example embodiment shown in FIG. 8.

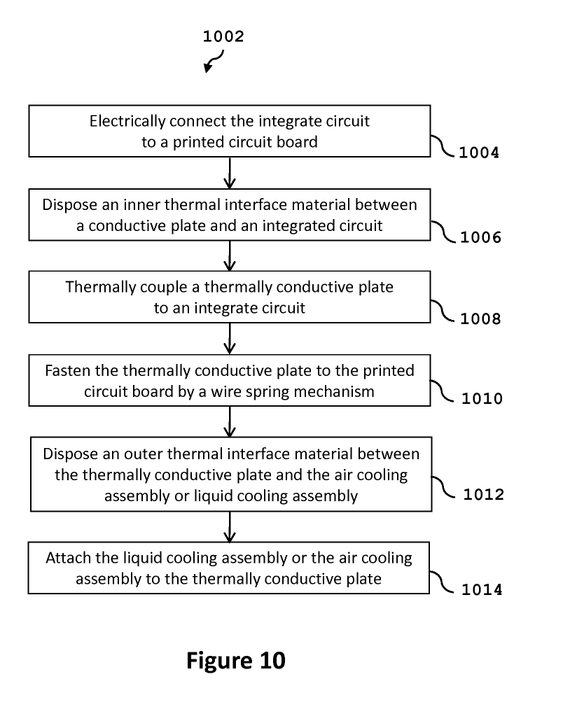

FIG. 10 shows an example embodiment of a method 1002 for providing cooling system interchangeability. In one embodiment, the method 1002 includes a circuit board connecting step 1004 of electrically connecting the integrated circuit to a printed circuit board. The method 1002 may include an inner thermal interface disposing step 1006 of disposing an inner thermal interface material between the thermally conductive plate and the integrated circuit. The method 1002 may include a conductive plate coupling step 1008 of thermally coupling a thermally conductive plate to an integrated circuit. In one embodiment, the thermally conductive plate is configured to couple interchangeably to a liquid cooling assembly or an air cooling assembly. It is noted that the liquid cooling assembly and the air cooling assembly are separate devices.

The method 1002 may include a spring wire mechanism fastening step 1010 of fastening the thermally conductive plate to the printed circuit board by a spring wire mechanism. The spring wire mechanism may include two or more wire springs, and each wire spring may be connected to a corresponding wire bail attached to the printed circuit board.

In one embodiment, the method 1002 includes testing the functionality of any of the integrated circuit, thermally conductive plate, and spring wire mechanism. From a practicality standpoint, the method 1002 allows a manufacturer to apply a particular cooling assembly as requested by the consumer instead of fabricating and storing a number of devices with air cooling systems and a number of devices with liquid cooling systems according to projected consumer demand. After manufacturing and testing the integrated circuit, spring wire mechanism, and/or thermally conductive plate, the manufacturer would have no immediate need to attach the air cooling assembly or liquid cooling assembly, but instead, the manufacturer could store the devices and then attach the appropriate cooling system as requested by the consumer.

In one embodiment, the method 1002 includes an outer thermal interface material disposing step 1014 of disposing an outer thermal interface material between the thermally conductive plate and either the air cooling assembly or liquid cooling assembly. The method 1002 may also include an assembly attaching step 1016 of attaching either the liquid cooling assembly or the air cooling assembly to the thermally conductive plate. In one embodiment, the air cooling assembly includes a heat sink configured to dissipate heat into air. In one embodiment, the liquid cooling assembly includes a cold plate configured to receive liquid from piping, and the piping may be configured to carry the liquid to and from the cold plate. Aspects of the method 1002 are described in further detail through FIGS. 1-3 and the accompanying description above.

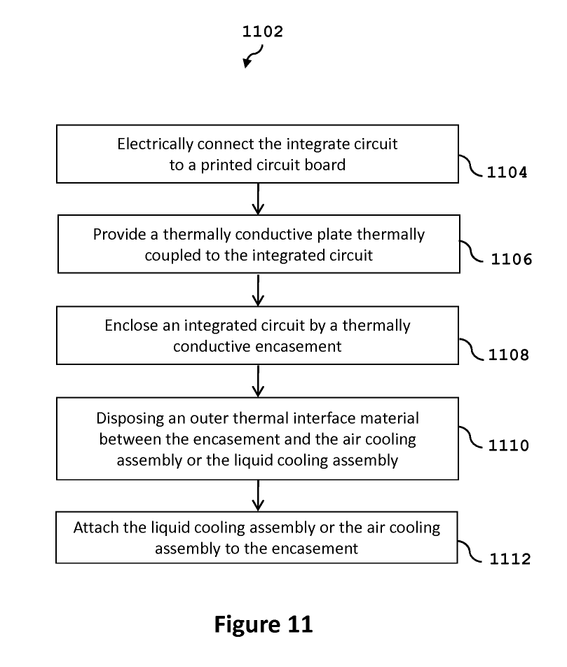

FIG. 11 shows an example embodiment of another method 1102 for providing cooling system interchangeability. In one embodiment, the method 1102 includes a circuit board connecting step 1104 of electrically connecting an integrated circuit to a printed circuit board. In one embodiment, the method 1102 includes a conductive plate providing step 1106 of providing a thermally conductive plate thermally coupled to the integrated circuit. In another embodiment, the conductive plate providing step 1106 is omitted. It is noted that the thermally conductive plate may be configured to couple interchangeably to the liquid cooling assembly and the air cooling assembly in the absence of the encasement. The method 1102 may include an enclosing step 1108 of enclosing the integrated circuit by a thermally conductive encasement. In one embodiment, the encasement is coupled to the printed circuit board. In embodiments that include the conductive plate providing step 1106, the enclosing step 1108 also includes enclosing the thermally conductive plate.

The encasement may be configured to couple interchangeably to a liquid cooling assembly or an air cooling assembly, and the encasement may be at least partially filled with a dielectric fluid thermally coupling the integrated circuit to the encasement. In one embodiment, the dielectric fluid is not circulated out of the encasement. It is noted that the liquid cooling assembly and the air cooling assembly are separate devices. For example, the air cooling assembly may include a heat sink configured to dissipate heat into air. The liquid cooling assembly, on the other hand, may include a cold plate configured to receive liquid from piping, and the piping may configured to carry the liquid to and from the cold plate.

The method 1102 may also include testing as described above for method 1002. The method 1102 may also include an outer thermal interface disposing step 1110 of disposing an outer thermal interface material between the encasement and either the air cooling assembly and liquid cooling assembly. In one embodiment, the method 1102 includes an assembly attaching step 1112 of attaching either the liquid cooling assembly or the air cooling assembly to the thermally conductive plate. Aspects of the method 1102 are described in further detail through FIGS. 4-9 and the accompanying description above.

While the preferred embodiments to the invention have been described, it will be understood that those skilled in the art, both now and in the future, may make various improvements and enhancements that fall within the scope of the claims which follow. These claims should be construed to maintain the proper protection for the invention first described.

What is claimed is:

1. An apparatus for providing cooling system interchangeability, the apparatus comprising:
a thermally conductive plate thermally coupled to an integrated circuit and configured to couple interchangeably to one of a liquid cooling assembly and an air cooling assembly, wherein the liquid cooling assembly and the air cooling assembly are separate devices.

2. The apparatus of claim 1, further comprising:
an inner thermal interface material disposed between the thermally conductive plate and the integrated circuit.

3. The apparatus of claim 1, further comprising:
a spring wire mechanism configured to fasten the thermally conductive plate to a printed circuit board, the spring wire mechanism having at least two wire springs, each wire spring connected to a corresponding wire bail, the wire bail configured to attach to the printed circuit board.

4. The apparatus of claim 1, wherein the air cooling assembly includes a heat sink configured to dissipate heat into air.

5. The apparatus of claim 1, wherein the liquid cooling assembly includes a cold plate configured to receive liquid from piping, the piping configured to carry the liquid to and from the cold plate.

6. The apparatus of claim 1, further comprising:
an outer thermal interface material disposed between the thermally conductive plate and one of the air cooling assembly and liquid cooling assembly, the outer thermal interface material thermally coupling the thermally conductive plate and one of the air cooling assembly and liquid cooling assembly.
